(19) United States
(12) Patent Application Publication
(10) Pub. No.: US 2010/0244821 A1
(43) Pub. Date: Sep. 30, 2010

(54) ROPE TESTER DEVICE

(75) Inventors: Koichiro Nishiyori, Tokyo (JP); Hiroshi Sasai, Tokyo (JP); Takashi Yoshioka, Tokyo (JP)

Correspondence Address: BUCHANAN, INGERSOLL & ROONEY PC, POST OFFICE BOX 1404, ALEXANDRIA, VA, 22313-1404, US

(73) Assignee: Mitsubishi Electric Corporation, Chiyoda-ku, Tokyo (JP)

(21) Appl. No.: 12/742,640

(22) PCT Filed: Nov. 13, 2007
(86) PCT No.: PCT/JP2007/071993

§ 371 Date: May 12, 2010

(51) Int. Cl. G01R 33/00

(52) U.S. Cl. 324/263

(57) ABSTRACT

In order to reduce noise due to the rope vibration in the rope tester, a mounting shaft extending perpendicular to the running direction of the wire rope is positioned in front of the rope tester, and a hook-shaped engagement piece, which extends from the rope tester and is slidable or rotatable into an opened or closed position, is brought into engagement with the mounting shaft so that the rope tester is held movable in the perpendicular direction relative to the running direction of the wire rope.

### TECHNICAL FILED

This invention relates to rope tester device for detecting a damage in wire rope and, more particularly, to a rope tester device suitable to detect a breakage of the rope strand of the rope used in an elevator hoist.

### BACKGROUND ART

The conventional rope tester device detects a damage of a wire rope by urging the rope tester against a running wire rope to magnetize it and by measuring a leaking magnetic flux from the damaged portion of the wire rope.

The support device for supporting the rope tester at a test position close to the wire rope includes an elastic member between the rope tester and a support arm fixed to the machine bed for elastically movably supporting the rope tester in the direction perpendicular to the running direction of the wire rope (see patent document 1, for example).

In such a rope tester, since the rope tester is elastically supported, the rope tester can move to follow the vibrating rope, and the relationship between the rope and the rope tester is maintained constant so that the generation of noise can be decreased. Also, since this rope tester is elastically urged by the elastic member against the wire rope, a function of suppressing the vibration of the wire rope is also provided.

[Patent Document 1] Japanese Patent Laid-Open No. H09-290973

### DISCLOSURE OF THE INVENTION

### Problem to be Solved by the Invention

However, in this rope tester device, the rope tester is urged by the elastic member against the rope for decreasing the rope vibration, the decrease of the vibration is determined by the elasticity (hard or soft) of the elastic member and it is difficult to maintain a balance between the magnetic attractive force of the rope tester acting on the rope and the support force for supporting the elastic member and to cope with the variation in amplitude of the vibration due to the change in the rope speed.

Accordingly, the object of the present invention is to provide a rope tester device in which it is ensured at a higher level that the vibration in the direction perpendicular to the running direction of the wire rope that greatly varies depending upon the rope speed can be reduced.

### Measure for Solving the Problem

The rope tester device of the present invention comprises a rope tester for detecting a damage of a wire rope by magnetizing a running wire rope and by measuring a leaking magnetic flux from the damaged portion of the rope, and a support device for supporting the rope tester at a test position close to the wire rope, the support device comprising a mounting shaft disposed on said test device and extending perpendicular to the running direction of the wire rope, and an engagement piece having one end connected to said rope tester and the other end engaging to said mounting shaft for making said rope tester movable in perpendicular direction relative to the running direction of said wire rope.

### ADVANTAGEOUS RESULTS OF THE INVENTION

With this structure, the rope vibration is suppressed by the magnetic attractive force of the rope tester, enabling the rope tester to easily follow the vibrating wire rope, resulting in a reduction of the vibration noise.

### BRIEF DESCRIPTION OF THE DRAWINGS

FIG. 1 is a schematic view illustrating the rope tester device of Embodiment 1 of the present invention being used is detecting the damages of the wire rope of the elevator; (Embodiment 1)

FIG. 2 is a perspective view of the rope tester device shown in FIG. 1;

### Embodiment 1

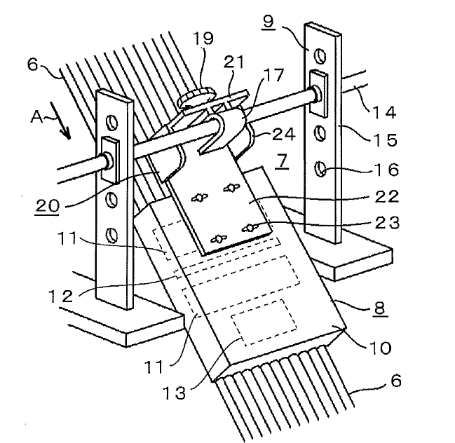

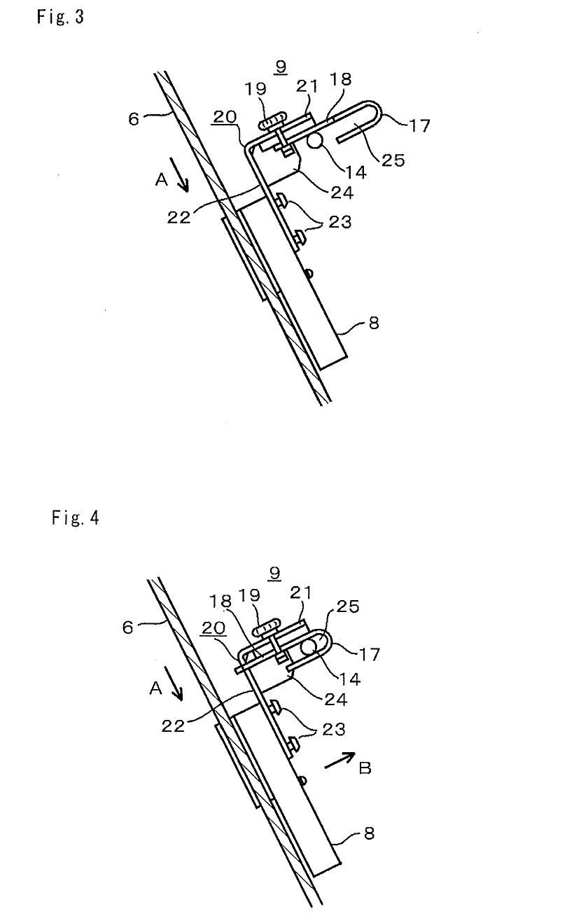

FIG. 3 is a schematic partial sectional view of the rope tester device shown in FIG. 1 in which the support device is in the open position;

### Embodiment 1

FIG. 4 is a schematic partial sectional view of the rope tester device shown in FIG. 1 in which the support device is in the closed position;

### Embodiment 1

FIG. 5 is a schematic partial sectional view of the rope tester device of Embodiment 2 of the present invention; (Embodiment 2)

FIG. 6 is a schematic partial sectional view of the rope tester device of Embodiment 3 of the present invention: (Embodiment 3)

### BEST MODE FOR CARRYING OUT THE INVENTION

The best mode for carrying out the present invention will now be described.

### Embodiment 1

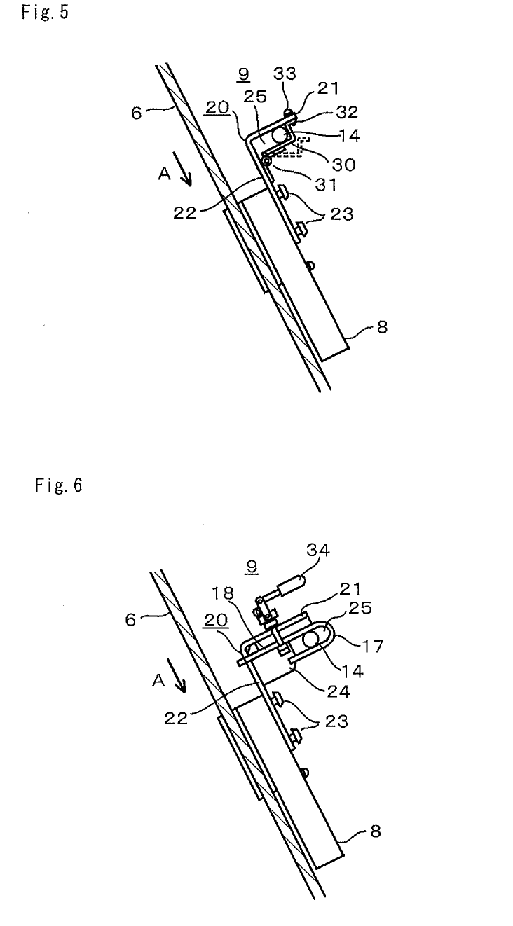

FIGS. 1-4 are views illustrating a rope tester device of Embodiment 1 of the present invention. FIG. 1 is a schematic view illustrating the rope tester device of Embodiment 1 of the present invention being used is detecting the damages of the wire rope of the elevator, FIG. 2 is a perspective view of the rope tester device shown in FIG. 1, FIG. 3 is a schematic partial sectional view of the rope tester device shown in FIG. 1 in which the support device is in the open position, and FIG. 4 is a schematic partial sectional view of the rope tester device shown in FIG. 1 in which the support device is in the closed position.

In FIG. 1, a hoist way 1 of an elevator is provided at its top portion with a machine bed 2, on which a machine room 3 is defined. The machine room 3 has provided therein a hoist machine 4 and a pulley 5 on which length of wire ropes 6 are wound for hoisting a car. A rope tester device 7 of this invention is disposed at a position on the machine bed 2 close to the wire ropes 6 extended between the hoist machine 4 and the pulley 5.

The rope tester device 7 comprises a rope tester 8 for detecting a damage of the wire ropes 6 by magnetizing the running wire ropes 6 and by measuring a leaking magnetic flux from a damaged portion of the ropes, and a support device 9 for supporting the rope tester 8 at a test position close to the wire ropes 6.

The rope tester 8 itself may be a known leakage magnetic flux type and, as shown in FIG. 2, comprises, within a box-shaped housing 10, a magnetizer 11, a probe 12 and a controller 13, for detecting a damage of the wire ropes 6 by magnetizing the wire ropes 6 by the magnetizer 11 and by detecting the leaking magnetic flux from the damaged portion of the wire ropes 6 and by processing the detected signal by the controller 13.

The support device 9 of the rope tester device 7 is, as shown in FIG. 2, disposed at the test position and comprises a mounting shaft 14 extending in a direction perpendicular to the running direction of the wire ropes 6 shown by an arrow A in FIG. 2 and parallel to the direction of the row of the plurality of wire ropes 6. The mounting shaft 14 is disposed on a leading edge side of the rope tester 8 as viewed in the running direction of the wire ropes 6, i.e., on the side at which the running wire ropes 6 first meet the rope tester 8. In the illustrated example, the mounting shaft 14 is disposed at the position further forwardly separated from and displaced upwardly from the leading edge of the rope tester 8.

The mounting shaft 14 is, in the illustrated example, a cylindrical shaft member supported by two support pillars fixed on the machine bed 2, the mounting shaft 14 being selectively inserted into a plurality of mounting holes 16 formed in the support pillars 15 so that its height position can be changed according to necessity. The height or the length of the support pillars 15 themselves may be made adjustable.

The support device 9 of the rope tester device 7 also comprises an engagement piece 17 having one end connected to the rope tester 8 and the other end engaging with the mounting shaft 14 for making the rope tester 8 movable in perpendicular direction relative to the running direction (the arrow A) of the wire ropes 6.

The engagement piece 17 is a hook made for example by bending a sheet metal into substantially J-shape for receiving and supporting the mounting shaft 14 in the hook portion. The longer leg portion of the engagement piece 17 has formed therein an elongated hole 18 (see FIGS. 3 and 4) extending in the length direction of the leg portion for receiving therein a stop screw 19 so that the position of the engagement piece 17 can be adjusted by the sliding structure. The hold-down screw 19 inserted into the elongated hole 18 extends through the rising leg portion 21 of the L-shaped bracket 20 mounted to the housing 10 of the rope tester 8 and the engagement piece 17 can be secured to the leg portion 21 of the bracket 20 when the hold-down screw 19 is tightened. The second leg portion 22 of the bracket 20 is position adjustably mounted to the housing 10 of the rope tester 8 by a securing means 23 including an elongated hole and a screw. The bracket 20 is provided with a rib 24 extending between two leg portions 21 and 22.

When a test of the wire ropes 6 by means of the rope tester device 7 of the present invention is to be conducted, the engagement piece 17 is moved to project from the bracket 20 by loosening the stop screw 19 to define an open portion between the tip portion of the shorter leg portion of the J of the hook-shaped engagement piece 17, thereby enabling the attachment and the detachment of the mounting shaft 14 through the opening portion. This position is an open position releasing the mounting shaft 14 from the engagement piece 17 of the support device 9.

The mounting shaft 14 of the rope tester device 7 is positioned at a suitable position on the support pillars 15 (see FIGS. 1 and 2) previously mounted on the machine bed 2, and the rope tester 8 in the open position is placed on and slid along the wire ropes 6 until the mounting shaft 14 is received from the opening portion of the engagement piece 17 and abuts against the inner surface of the engagement piece 17. This state is shown in FIG. 3.

Then, the engagement piece 17 is slid downward to move into the closed position in which the opening portion of the engagement piece 17 is closed and the hold-down screw 19 is tightened to secure the engagement piece 17 to the bracket 20. This state is shown in FIG. 4. At this time, the mounting shaft 14 is received with a play within a closed space 25 defined by the hook-shaped engagement piece 17 and the rib 24 of the bracket 20, wherein it is slidable in the direction shown by the arrow B shown in FIG. 4 and perpendicular to the running direction of the wire ropes 6 while it is substantially not movable in the direction of the running direction A of the wire ropes 6.

Thus, when the rope tester 8 is operated with the rope tester device 7 set at the wire ropes 6 to be tested and the wire ropes 6 run in the direction of the arrow A by operating the elevator apparatus in the inspection and maintenance mode, the rope tester 8 slides along the wire ropes 6 while being attracted by the magnetic attractive force and the detection of the damages in the ropes can be achieved by measuring the leakage magnetic flux.

According to this arrangement, the rope tester 8 in its entirety follows the vibration in the vertical direction of the rope which greatly varies in the amplitude in accordance with the change in the speed of the wire ropes 6, so that the effect of the noise of the rope tester 8 due to the vibration can be reduced. Also, since the movement of the rope tester 8 is limited in the longitudinal direction (the running direction) of the wire ropes 6, the rope tester 8 does not move in the longitudinal direction of the rope by the friction and/or the magnetic attractive force between the wire ropes 6 and the rope tester 8.

The mounting shaft 14 is disposed in front of the rope tester 8 i.e., it is arranged so that the rope tester 8 is positioned at the downstream of the mounting shaft 14. This structure allows, assuming that the running direction of the wire ropes 6 is as shown by the arrow A in FIG. 2, even when the abnormal portion (broken wire element, broken strand, expanded rope diameter and deposit of foreign matter) of the wire ropes 6 impinges at the rope tester 8, the rope tester 8 rotates about the mounting shaft 14 to elude the obstacle or the abnormal portion. This enables the possibility of the elevator system and the rope tester 8 to be damaged to be low.

Also, the engagement piece 17 can be attached to or detached from the mounting shaft 14 by moving as shown in FIGS. 3 and 4 by tightening or loosening the hold-down screw 19. In this arrangement, the mounting of the rope tester 8 can be achieved by attaching the rope tester 8 to the wire ropes 6 by the magnetic attractive force with the engagement piece 17 positioned in the open position shown in FIG. 2, moving the rope tester 8 and the engagement piece 17 downward along the wire ropes 6 until the engagement piece 17 is brought into contact with the mounting shaft 14, and by sliding the engagement piece 17 toward the ropes into the position shown in FIG. 4.

### Embodiment 2

In the rope tester device shown in FIG. 5, an open-close structure is provided in which an engagement piece 30 which is an L-shaped hook is movably mounted to the bracket 20 by a hinge 31 so that the engagement piece 30 engages at its inner surface with the mounting shaft 14 and can be secured at its free end 32 to the bracket 20 by a screw 33. Thus, the engagement piece 30 is movable between a closed position in which the mounting shaft 14 is accommodated within a closed space 25 as illustrated in solid lines in FIG. 3 and an open position in which the screw 33 is loosened and the mounting shaft 14 can be freely attached or detached.

In this structure, a space perpendicular to the running direction A of the wire ropes 6 can be made small. In stead of the screw 33, a clip may be used to detachably fasten the engagement piece 30 and the bracket 20, or a clip-shaped bent portion may be provided at the tip of the engagement piece 30 so that the attachment is achieved by the elasticity of the engagement piece 30.

### Embodiment 3

In FIG. 6, the fastening member for detachably fastening the engagement piece 17 to the bracket 20 is a toggle structure employing a toggle clamp 34 in stead of the stop screw 19 of the embodiments shown in FIGS. 1-4. The engagement piece 17 is fixed in the closed position shown in FIG. 6 by moving the toggle clamp 34 in the fallen position, and it can be slid into the open position by moving the toggle clamp 34 in the raised position. This structure enables the opening and closing of the hook or the engagement piece 17 by a single action.

The embodiments heretofore described as the best mode for carrying out the invention are only for showing examples of the application of the present invention and not limiting the present invention. Also, the features of the various embodiments may be suitably combined and carried out.

1. A rope tester device comprising;
a rope tester for detecting a damage of a wire rope by magnetizing a running wire rope and by measuring a leaking magnetic flux from the damaged portion of the rope; and
a support device for supporting the rope tester at a test position close to the wire rope;
said support device comprising;
a mounting shaft disposed on said test device and extending perpendicular to the running direction of the wire rope; and
an engagement piece having one end connected to said rope tester and the other end engaging to said mounting shaft for making said rope tester movable in perpendicular direction relative to the running direction of said wire rope.

2. The rope tester device as claimed in claim 1, wherein said engagement piece is a hook for making said rope tester rotatable about said mounting shaft.

3. The rope tester device as claimed in claim 1, wherein said mounting shaft is disposed at the leading edge side of said rope tester as seen in the running direction of the wire rope.

4. The rope tester device as claimed in claim 1, wherein said engagement piece is supported on a bracket mounted on said rope tester.

5. The rope tester device as claimed in claim 1, wherein said engagement piece is movable between a closing position on said mounting shaft and an open position releasing said mounting shaft.

6. The rope tester device as claimed in claim 5, wherein said engagement piece is movable between said closing position and said open position by a sliding structure.

7. The rope tester device as claimed in claim 5, wherein said engagement piece is movable between said closing position and said open position by a hinge structure.

8. The rope tester device as claimed in claim 5, wherein said engagement piece is fixed at said closing position by a tightening member.

9. The rope tester device as claimed in claim 2, wherein said engagement piece is movable between a closing position on said mounting shaft and an open position releasing said mounting shaft.

10. The rope tester device as claimed in claim 3, wherein said engagement piece is movable between a closing position on said mounting shaft and an open position releasing said mounting shaft.

11. The rope tester device as claimed in claim 4, wherein said engagement piece is movable between a closing position on said mounting shaft and an open position releasing said mounting shaft.
